(19) United States
(12) Patent Application Publication
(10) Pub. No.: US 2024/0347684 A1
(43) Pub. Date: Oct. 17, 2024

(54) DISPLAY APPARATUS AND METHOD OF MANUFACTURING THE SAME

(71) Applicant: Japan Display Inc., Tokyo (JP)

(72) Inventors: Yoshikatsu IMAZEKI, Tokyo (JP); Yoichi KAMIJO, Tokyo (JP); Koichi MIYASAKA, Tokyo (JP); Shuichi OSAWA, Tokyo (JP); Yoshifumi KAMEI, Tokyo (JP)

(73) Assignee: Japan Display Inc., Tokyo (JP)

(21) Appl. No.: 18/627,457

(22) Filed: Apr. 5, 2024

(30) Foreign Application Priority Data
Apr. 13, 2023 (JP) 2023-065679

(51) Int. Cl. H01L 33/62; H01L 25/075

(52) U.S. Cl. CPC H01L 33/62; H01L 25/0753; H01L 2933/0066

(57) ABSTRACT

Performance of a display apparatus is improved. A display apparatus includes: an LED element and a diode element. An anode electrode of the diode element is connected to a cathode electrode of the LED element through a second terminal pattern and a second bump electrode. A cathode electrode of the diode element is connected to an anode electrode of the LED element through a first terminal pattern and a first bump electrode.

### CROSS-REFERENCE TO RELATED APPLICATION

The present application claims priority to Japanese Patent Application No. 2023-065679 filed on Apr. 13, 2023, the disclosure of which is incorporated herein by reference.

### TECHNICAL FIELD OF THE INVENTION

The present invention relates to a display apparatus and a method of manufacturing the same.

### BACKGROUND OF THE INVENTION

A Light Emitting Diode (LED) display apparatus in which light emitting diode elements that are self-luminous elements are arranged in matrix form on a substrate is exemplified as the display apparatus. For example, Japanese Patent Application Laid-open Publication No. 2020-67626 (Patent Document 1) describes a display apparatus in which a plurality of microLEDs are arranged on a substrate.

### SUMMARY OF THE INVENTION

An LED display apparatus forms a display image by using a switching element to control an operation of a lot of LED elements mounted on a substrate. A thin-film transistor is used as the switching element. When the switching element is irradiated with light emitted from the LED element, leakage current is generated in the switching element, and this may be a cause of a decrease in luminance. On the other hand, in consideration of a degree of freedom of design, less obstructive factors for positions of the switching element and the LED element in plan view are preferable. The following is a method for solving this problem.

A display apparatus according to an embodiment includes: a first diode element including a first anode electrode and a first cathode electrode and being an inorganic light emitting diode element; and a substrate structure on which the first diode element is mounted. The substrate structure includes: a first terminal connected to the first anode electrode; a second terminal connected to the first cathode electrode; a second diode element electrically connected to each of the first terminal and the second terminal; a first bump electrode formed on the first terminal and connected to each of the first terminal and the first anode electrode; and a second bump electrode formed on the second terminal and connected to each of the second terminal and the first cathode electrode. The second diode element includes: a second cathode electrode connected to the first terminal; and a second anode electrode connected to the second terminal.

A method of manufacturing a display apparatus according to another embodiment includes: a step (a) of preparing a substrate structure including a first terminal and a second terminal; a step (b) of forming a first bump electrode on the first terminal and a second bump electrode on the second terminal; a step (c) of preparing a first diode element including a first anode electrode and a first cathode electrode and being an inorganic light emitting diode element, and connecting the first anode electrode to the first bump electrode while connecting the first cathode electrode to the second bump electrode. The substrate structure includes a second diode element electrically connected to each of the first terminal and the second terminal. The second diode element includes a second cathode electrode connected to the first terminal and a second anode electrode connected to the second terminal. The step (b) includes a step of forming the first bump electrode and the second bump electrode by an electroplating method.

### BRIEF DESCRIPTIONS OF THE DRAWINGS

FIG. 1 is a plan view showing a configuration example of a display apparatus according to an embodiment.

FIG. 2 is a circuit diagram showing a configuration example of a circuit around a pixel shown in FIG. 1.

FIG. 3 is an enlarged transparent plan view showing an example of a peripheral structure of an LED element arranged in each of a plurality of pixels of the display apparatus shown in FIG. 1.

FIG. 4 is an enlarged cross-sectional view taken along a line A-A of FIG. 3.

FIG. 5 is an enlarged cross-sectional view showing a detailed structure example of a bump electrode shown in FIG. 4.

FIG. 6 is an enlarged cross-sectional view showing a step of forming a first-layer metal film on a terminal pattern shown in FIG. 5.

FIG. 7 is an enlarged cross-sectional view showing a step of forming a second-layer metal film on a terminal pattern shown in FIG. 5.

FIG. 8 is an enlarged cross-sectional view showing a step of forming a third-layer metal film on a terminal pattern shown in FIG. 5.

FIG. 9 is a transparent plan view showing one pixel of a display apparatus according to a modification example relative to FIG. 3.

FIG. 10 is an enlarged cross-sectional view taken along a line B-B of FIG. 9.

FIG. 11 is a transparent plan view showing a modification example relative to a diode element shown in FIG. 9.

FIG. 12 is an enlarged cross-sectional view taken along a line C-C of FIG. 11.

FIG. 13 is a flowchart showing an example of a method of manufacturing the display apparatus.

### DESCRIPTIONS OF THE PREFERRED EMBODIMENTS

The following is explanation on each embodiment of the present invention with reference to drawings. Note that only one example is disclosed, and appropriate modification with keeping the concept of the present invention which can be easily anticipated by those who are skilled in the art is obviously within the scope of the present invention. Also, in order to make the explanation clear, a width, a thickness, a shape, and others of each portion in the drawings are schematically illustrated more than those in an actual aspect in some cases. However, the illustration is only one example, and does not limit the interpretation of the present invention. In the present specification and each drawing, similar elements to those described earlier for the already-described drawings are denoted with the same or similar reference characters, and detailed description for them is appropriately omitted in some cases.

In the following embodiments, a microLED display apparatus including a plurality of microLED elements will be exemplified and explained as an example of the display apparatus using the plurality of inorganic light emitting elements. The microLED element has a merit capable of displaying high-definition images because of having a smaller element size (outer shape dimension) than that of a general LED element.

Note that an Organic Light-Emitting (OLED) is exemplified as the light emitting diode element that is the self-luminous element. The inorganic light emitting diode element (microLED element) explained in the following embodiments is distinguished from the organic light emitting diode element. A display apparatus using the inorganic light emitting diode element has higher reliability as the LED element than a display apparatus using the organic light emitting diode element, and therefore, has been expected to be used for a case requiring high luminance.

### <Display Apparatus>

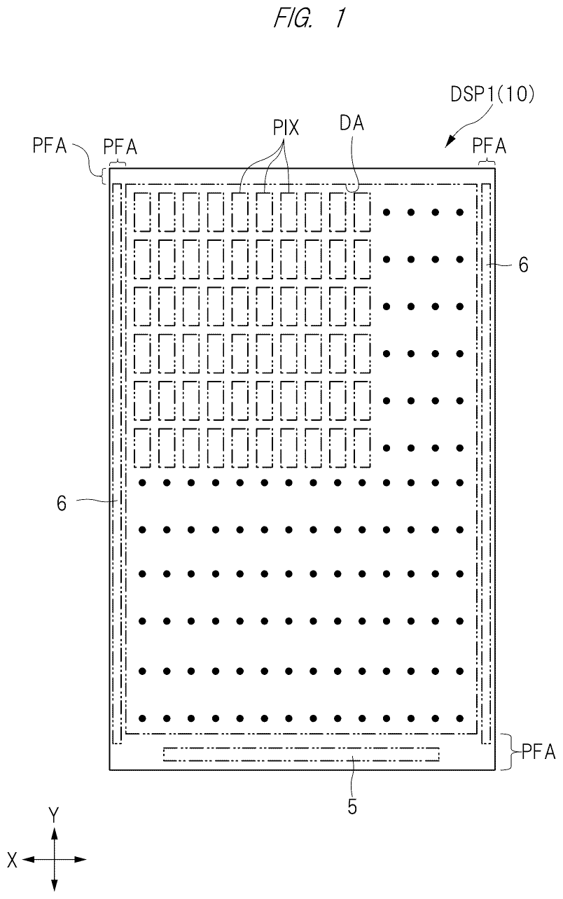

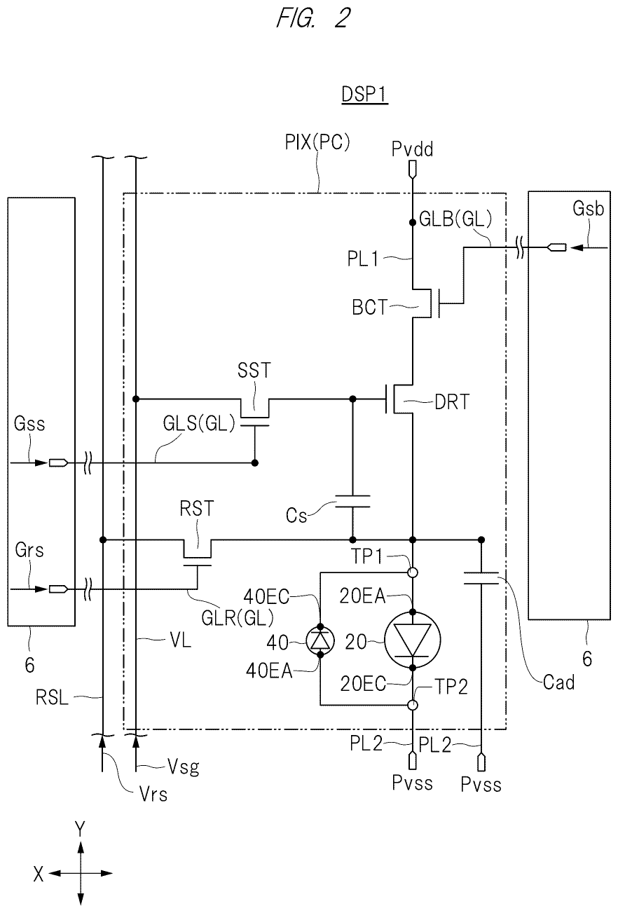

First, a configuration example of a microLED display apparatus that is the display apparatus of the present embodiment will be described. FIG. 1 is a plan view showing a configuration example of the display apparatus according to an embodiment. In FIG. 1, each of a boundary between a display region DA and a peripheral region PFA, a control circuit 5, a drive circuit 6, and a plurality of pixels PIX is illustrated with a dashed double-dotted line. FIG. 2 is a circuit diagram showing a configuration example of a circuit around the pixel shown in FIG. 1. Note that a pixel circuit PC shown in FIG. 2 is illustrated as an example of an equivalent circuit corresponding to one pixel PIX shown in FIG. 1.

FIG. 1 shows an X direction and a Y direction. The X direction and the Y direction cross each other. In an example explained below, the X direction is orthogonal to the Y direction.

An X-Y plane including the X direction and the Y direction will be explained below as a plane parallel to a display surface of the display apparatus. In the following explanation, a term “plan view” means viewing of a plane parallel to the X-Y plane unless otherwise particularly stated that the term is to be interpreted in different meaning. Also, as described later, a normal-line direction to the X-Y plane will be explained as a “Z direction” or a thickness direction. The X direction, the Y direction and the Z direction are directions crossing one another, more specifically being orthogonal to one another.

The explanation of the present specification may describe that “A” is “covered” with “B”. This phrase “A is covered with B” means that the entire A overlaps B in plan view that is viewing of the X-Y plane described above. In addition, the phrase “A is covered with B” may be rephrased as “the entire A overlaps B in the thickness direction (Z direction)” as described above.

As shown in FIG. 1, a display apparatus DSP1 of the present embodiment includes the display region DA, the peripheral region PFA surrounding the display region DA in a frame form, and the plurality of pixels PIX arranged in a matrix form within the display region DA. The display apparatus DSP1 also includes a substrate 10, the control circuit 5 formed on the substrate 10, and the drive circuit 6 formed on the substrate 10.

The control circuit 5 is a control circuit that controls driving of a displaying function of the display apparatus DSP1. For example, the control circuit 5 is a driver IC (Integrated Circuit) mounted on the substrate 10. In the example shown in FIG. 1, the control circuit 5 is arranged along one short side among four sides of the substrate 10. In an example of the present embodiment, the control circuit 5 includes a signal line drive circuit (video driver) that drives video signal lines VL (see FIG. 2) connected to the plurality of pixels PIX. However, the position and configuration example of the control circuit 5 are not limited to the example shown in FIG. 1, but there are various modification examples thereof. For example, in FIG. 1, a circuit board such as a flexible printed board may be connected to the position shown as the control circuit 5, and the above-described driver IC may be mounted on the circuit board. In addition, for example, the signal line drive circuit that drives the video signal lines VL may be formed separately from the control circuit 5.

The drive circuit (scan driver) 6 is a circuit that drives scan signal line GLB, GLR and GLS (see FIG. 2) of the plurality of pixels PIX. The drive circuit 6 drives the plurality of scan signal lines GL based on a control signal from the control circuit 5. In the example shown in FIG. 1, the drive circuit 6 is arranged along each of two long sides among four sides of the substrate 10. In the example shown in FIG. 1, the display region DA is arranged between two drive circuit 6 in plan view. However, the position and configuration example of the drive circuit 6 are not limited to the example shown in FIG. 1, but there are various modification examples thereof. For example, in FIG. 1, a circuit board such as a flexible printed board may be connected to the position shown as the control circuit 5, and the above-described drive circuit 6 may be mounted on the circuit board.

Next, a configuration example of the pixel circuit PC for driving the pixel PIX shown in FIG. 1 will be described with reference to FIG. 2. Note that one pixel circuit PC for driving one pixel PIX is exemplified as a representative example and illustrated in FIG. 2. Each of the plurality of pixels PIX shown in FIG. 1 includes the same circuit as the pixel circuit PC shown in FIG. 2. The pixel circuit PC is a voltage signal type circuit that controls a light emitting state of an LED element (inorganic light emitting diode element, diode element) 20 in accordance with a video signal Vsg supplied from the control circuit 5 (see FIG. 1).

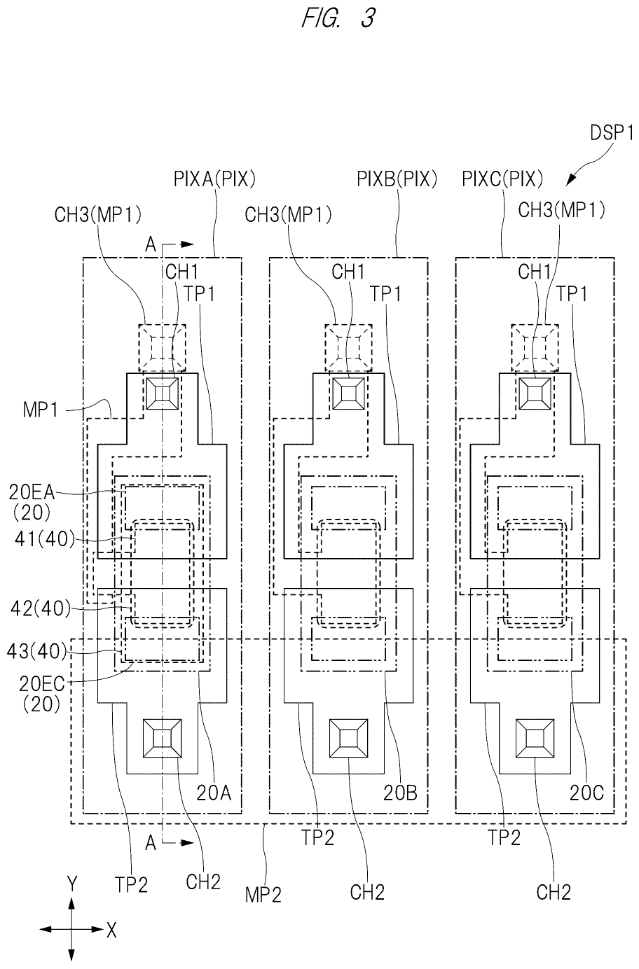

As shown in FIG. 2, the pixel PIX includes the LED element 20. The LED element 20 is the micro light-emitting diode described above. The LED element 20 includes an anode electrode 20EA (see FIG. 3 described later) and a cathode electrode 20EC (see FIG. 3 described later).

The display region DA of the display apparatus DSP1 includes a plurality of types of wirings. These wirings include the plurality of scan signal lines GLS, GLR and GLB, the plurality of video signal lines VL, a plurality of power supply lines PL1, a plurality of power supply lines PL2 and a plurality of reset wirings RSL.

The scan signal lines GLS, GLR and GLB extend in the X direction, and are connected to the drive circuit 6. For example, as shown in FIG. 1, the scan signal lines GLS, GLR and GLB for driving the even-numbered pixel PIX of the pixels PIX arranged in the Y direction are connected to one of the drive circuits 6 while the scan signal lines GLS, GLR and GLB for driving the odd-numbered pixel PIX are connected to the other of the drive circuits 6. As another example, for example, any of the scan signal lines GLS, GLR and GLB may be connected to one of the drive circuits 6 while the rest of the scan signal lines GLS, GLR and GLB may be connected to the other of the drive circuits 6, such that all the scan signal lines GLS and GLR are connected to one of the drive circuits 6 while all the scan signal lines GLB are connected to the other of the drive circuits 6.

The video signal lines VL, the power supply lines PL1 and PL2 and the reset wiring RSL extend in the Y direction. The video signal line VL is connected to the control circuit 5 (see FIG. 1). A video signal Vsg and an initialization signal are supplied from the control circuit 5 to the video signal line VL. A high potential Pvdd is supplied from the control circuit 5 to the power supply line PL1. A low potential Pvss lower than the high potential Pvdd is supplied from the control circuit 5 to the power supply line PL2. A rest signal Vrs is supplied from the control circuit 5 to the reset wiring RSL.

The control circuit 5 outputs a start pulse signal or a clock signal not illustrated to the drive circuit 6. The drive circuit 6 includes a plurality of shift register circuits, sequentially transfers the start pulse signal to a shift register circuit of a next stage in response to the clock signal, and sequentially supplies the scan signal to each of the scan signal lines GLS, GLR and GLB.

The pixel circuit PC controls the LED element 20 in response to the video signal Vsg supplied to the video signal line VL. In order to achieve such control, the pixel circuit PC according to the present embodiment includes a rest transistor (switching element) RST, a pixel selection transistor (switching element) SST, an output transistor (switching element) BCT, a drive transistor (switching element) DRT, a holding capacitance Cs and an auxiliary capacitance Cad. The auxiliary capacitance Cad is an element for adjusting a light-emitting current volume, and may be unnecessary depending on cases.

Each of the rest transistor RST, the pixel selection transistor SST, the output transistor BCT and the drive transistor DRT is a switching element made of a Thin Film Transistor (TFT). A conductivity type of the thin film transistor is not particularly limited. For example, each of all transistors may be made of an N-channel type TFT, or at least one of these transistors may be made of a P-channel type TFT.

In the present embodiment, the rest transistor RST, the pixel selection transistor SST, the output transistor BCT and the drive transistor DRT are formed by the same step to have the same layer structure as one another, and have a bottom gate structure polycrystal silicon is used for a in which semiconductor layer. As another example, the rest transistor RST, the pixel selection transistor SST, the output transistor BCT and the drive transistor DRT may have a top gate structure. Note that oxide semiconductor, polycrystal GaN semiconductor or others may be used for the semiconductor layer.

Each of the rest transistor RST, the pixel selection transistor SST, the output transistor BCT and the drive transistor DRT includes a source electrode, a drain electrode and a gate electrode. The gate electrode included in each transistor is also referred to as control electrode. The source electrode and the drain electrode included in each transistor is simply referred to as electrode.

The drive transistor DRT and the output transistor BCT are connected in series to the LED element 20, between the power supply lines PL1 and PL2. The high potential Pvdd supplied to the power supply line PL1 is set to, for example, 10 V, and the low potential Pvss supplied to the power supply line PL2 is set to, for example, 1.5 V.

The drain electrode of the output transistor BCT is connected to the power supply line PL1. The source electrode of the output transistor BCT is connected to the drain electrode of the drive transistor DRT. The gate electrode of the output transistor BCT is connected to the scan signal line GLB. The output transistor BCT is turned ON/OFF by a control signal Gsb supplied to the scan signal line GLB. In this case, “ON” represents an electrical connection state, and “OFF” represents an electrical disconnection state. The output transistor BCT controls light emitting time of the LED element 20, based on the control signal Gsb.

The source electrode of the drive transistor DRT is connected to one electrode (in this case, the anode electrode 20EA) of the LED element 20. The other electrode (in this case, the cathode electrode 20EC) of the LED element 20 is connected to the power supply line PL2. The drive transistor DRT outputs a drive electric current depending on the video signal Vsg to the LED element 20.

The source electrode of the pixel selection transistor SST is connected to the video signal line VL. The drain electrode of the pixel selection transistor SST is connected to the gate electrode of the drive transistor DRT. The gate electrode of the pixel selection transistor SST is connected to the scan signal line GLS functioning as a gate wiring for signal writing control. The pixel selection transistor SST is turned ON/OFF by a control signal Gss supplied from the scan signal line GLS to switch a state between the pixel circuit PC and the video signal line VL to a connection state or a disconnection state. In other words, when the pixel selection transistor SST is turned ON, the video signal Vsg of the video signal line VL or the initialization signal is supplied to the gate electrode of the drive transistor DRT.

The source electrode of the reset transistor RST is connected to the reset wiring RSL. The drain electrode of the reset transistor RST is connected to the source electrode of the drive transistor DRT and the anode electrode 20EA of the LED element 20. The gate electrode of the reset transistor RST is connected to the scan signal line GLR functioning as a gate wiring for rest control. The reset transistor RST is turned ON/OFF by a control signal Grs supplied from the scan signal line GLR. When the reset transistor RST is turned ON, potentials of the source electrode of the drive transistor DRT and the anode electrode 20EA of the LED element 20 can be reset by a reset signal Vrs of the reset wiring RSL. In other words, the reset wiring RSL is a wiring for resetting the voltage of the LED element 20.

The holding capacitance Cs is connected between the gate electrode and the source electrode of the drive transistor DRT. The auxiliary capacitance Cad is connected between the source electrode of the drive transistor DRT and the power source line PL2.

The drive circuit 6 sequentially supplies the control signals Gss, Grs and Gsb to the scan signal lines GLS, GLR and GLB of each line (a series of pixels PIX in the X direction), based on the start pulse signal and the clock signal. The control circuit 5 sequentially supplies the video signal Vsg and the initialization signal to each video signal line VL, based on the signal supplied from the control circuit 5 shown in FIG. 2. The electric charge held in the holding capacitance Cs by the supply of the video signal Vsg is initialized by the supply of the initialization signal.

In such a configuration described above, the pixel circuit PC is driven by the control signals Gss, Grs and Gsb supplied to the scan signal lines GLS, GLR and GLB, and the LED element 20 emits the light having a luminance depending on the video signal Vsg of the video signal line VL.

Incidentally, the present embodiment includes a diode element 40 in addition to the LED element 20. The diode element 40 is a rectifying element in which electric current is easier to flow at the time of voltage application in a forward direction than voltage application in a reverse direction. The diode element 40 is not a light emitting element. Detailed structure example and characteristics of the diode element 40 will be described later.

### <Peripheral Structure of LED Element>

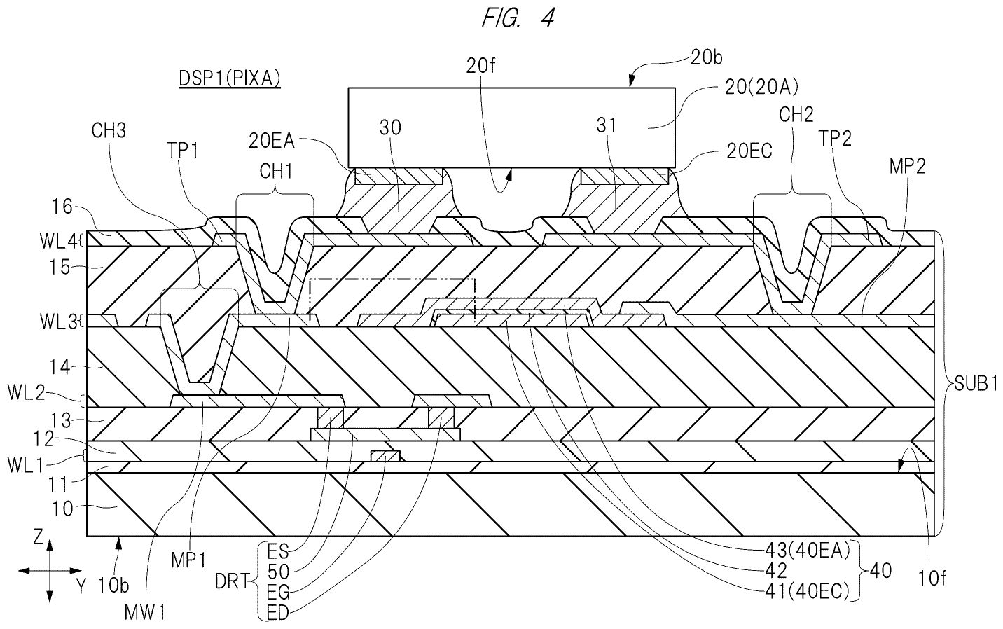

Next, a peripheral structure of the LED element arranged in the pixel PIX shown in FIG. 1 will be explained. FIG. 3 is an enlarged transparent plan view showing an example of the peripheral structure of the LED element arranged in each of the plurality of pixels of the display apparatus shown in FIG. 1. FIG. 4 is an enlarged cross-sectional view taken along a line A-A in FIG. 3.

In FIG. 3, the conductor pattern arranged in the wiring layer WL4 shown in FIG. 4 is illustrated with a solid line, each of the diode element 40 arranged in the wiring layer WL3 and the conductor pattern connected to the diode element 40 is illustrated with a dotted line, and each outline of the LED element 20 and the electrode included in the LED element 20 is illustrated with a dashed double-dotted line. The pixel PIXA, the pixel PIXB, and the pixel PIXC shown in FIG. 3 have the same structure as one another. Therefore, FIG. 4 shows the structure of the pixel PIXA (see FIG. 3) as a representative example. However, the pixel PIXB and the pixel PIXC shown in FIG. 3 also have the same cross-sectional structure.

In the following explanation, the terms “terminal pattern TP1” and “terminal pattern TP2” are used for the explanation. The term “terminal pattern” means a conductor pattern including a terminal portion used for electrical connection of an external device, and can be rephrased and applied as terminal.

The pixel circuit PC shown in FIG. 2 is the circuit corresponding to each of the pixel PIXA, the pixel PIXB and the pixel PIXC shown in FIG. 3. Therefore, each of the pixel PIXA, the pixel PIXB, and the pixel PIXC shown in FIG. 3 includes the reset transistor RST, the pixel selection transistor SST, the output transistor BCT, and the drive transistor DRT described with reference to FIG. 2. Similarly, each of the pixel PIXA, the pixel PIXB and the pixel PIXC shown in FIG. 3 includes the holding capacitance Cs and the auxiliary capacitance Cad described with reference to FIG. 2.

As shown in FIG. 4, the display apparatus DSP1 includes a substrate structure SUB1 and an LED element (inorganic light emitting diode element) 20 mounted on the substrate structure SUB1. The substrate structure SUB1 of the display apparatus DSP1 includes a plurality of insulating layers arranged between a plurality of wiring layers. The LED element 20 is mounted on the wiring layer WL4 arranged in the topmost layer among the plurality of wiring layers. The substrate structure SUB1 of the display apparatus DSP1 includes a transistor as a switching element. In FIG. 4, the drive transistor DRT is illustrated as an example of the switching element arranged on the substrate 10. However, on the substrate 10 (more specifically, on the insulating layer 11), each of the reset transistor RST, the pixel selection transistor SST, the output transistor BCT, and the drive transistor DRT described with reference to FIG. 2 is arranged. Each of the reset transistor RST, the pixel selection the output transistor BCT, and the drive transistor SST, transistor DRT shown in FIG. 2 has the same structure as that of the drive transistor DRT shown in FIG. 4 described later.

As shown in FIG. 3, the display apparatus DSP1 includes a plurality of LED elements 20. Among the plurality of LED elements 20 of the display apparatus, FIG. 3 shows an LED element 20A, an LED element 20B next to the LED element 20A, and an LED element 20C next to the LED element 20B.

As shown in FIG. 4, the LED element 20 has a surface 20f and a surface 20b opposite the surface 20f. The LED element 20 includes a plurality of (in FIG. 3, two) electrodes arranged on the surface 20f. The plurality of electrodes include an anode electrode 20EA and a cathode electrode 20EC. The anode electrode 20EA is electrically connected to the terminal pattern TP1 through the bump electrode 30. The cathode electrode 20EC is electrically connected to the terminal pattern TP2 through the bump electrode 31.

Among the conductor patterns included in the substrate structure SUB1, the terminal pattern TP1 and the terminal pattern TP2 are conductor patterns each including a portion that functions as a “terminal” used for electrically connecting the LED element 20 and the substrate structure SUB1.

The display apparatus DSP1 displays images by driving each of the plurality of LED elements 20 mounted on the substrate structure SUB1. Light emitted from the LED elements 20 is emitted in all directions from the surfaces 20f, 20b, and four side surfaces.

The substrate 10 has the surface 10f and the surface 10b opposite to the surface 10f. A plurality of wiring layers and a plurality of insulating layers are stacked on the surface 10f of the substrate 10. The substrate 10 is, for example, a glass substrate made of glass. However, there are various modification examples of a material configuring the substrate 10. For example, a resin substrate made of resin may be used.

In the example shown in FIG. 4, the plurality of wiring layers included in the display apparatus DSP1 include a wiring layer WL4, a wiring layer WL3, a wiring layer WL2 and a wiring layer WL1, which are stacked in this order from the wiring layer WL4 to the substrate 10. The plurality of insulating layers included in the display apparatus DSP1 include insulating layers 11, 12, 13, 14, and 15, which are stacked in this order from the surface 10f of the substrate 10.

The insulating layer 11 is a base layer of the thin-film transistor, and is an inorganic insulating layer made of an inorganic material. The wiring layer WL1 is arranged on the insulating layer 11, and is covered with the insulating layer 12. The conductor pattern formed in the wiring layer WL1 includes the gate electrode EG shown in FIG. 4 and the scan signal lines GLB, GLS, and GLR described with reference to FIG. 2. The insulating layer 12 is also an inorganic insulating layer made of an inorganic material. A portion of the insulating layer 12, the portion being arranged between the gate electrode EG of the transistor and the semiconductor layer 50, functions as a gate insulating film.

The drive transistor DRT including the gate electrode EG includes the semiconductor layer 50, the gate electrode EG, the source electrode ES, and the drain electrode ED. In the example shown in FIG. 4, the thin-film transistor with the bottom gate structure is shown as an example. However, the top gate structure may be used as described above. The gate electrode EG is arranged on the insulating layer 11. The semiconductor layer 50 is arranged on the insulating layer 12. One portion of the semiconductor layer 50 corresponds to a source region, and the source electrode ES is connected to the source region. The other portion of the semiconductor layer 50 corresponds to a drain region, and the drain electrode ED is connected to the drain region. A region between the source region and the drain region functions as a channel region.

The wiring layer WL2 is arranged on the insulating layer 13 covering the drive transistor DRT. The insulating layer 13 is an inorganic insulating layer made of an inorganic material. The conductor pattern formed in the wiring layer WL2 includes a wiring connected to each of the plurality of transistors. For example, as shown in FIG. 4, a wiring pattern MW1 connected to the source electrode ES of the drive transistor DRT is included in the wiring layer WL2. The conductor patterns formed in the wiring layer WL2 include the video signal line VL, the power supply line PL1, the power supply line PL2, and the reset wiring RSL shown in FIG. 2.

The wiring layer WL2 includes a wiring pattern MW1 electrically connected to the conductor pattern MP1 through a contact hole CH3 formed in the insulating layer 14 and electrically connected to the electrode (source electrode ES) of the drive transistor DRT.

Each of the insulating layer 14 covering the wiring layer WL2 and the insulating layer 15 stacked on the insulating layer 14 is an organic insulating film made of an organic material. The insulating layer 14 is an insulating layer arranged between the wiring layer WL2 and the wiring layer WL3. The insulating layer 15 is an insulating layer arranged between the wiring layer WL3 and the wiring layer WL4. As shown in FIG. 4, a contact hole is used for electrical connection between the wiring layer WL2 and the wiring layer WL3 and electrical connection between the wiring layer WL3 and the wiring layer WL4. The organic insulating layer has better embeddability in the opening (such as the contact hole) than that of the inorganic insulating layer. In other words, in the case of the organic insulating layer, even if the base member has an opening, its upper surface can be easily flattened. Therefore, each of the insulating layer 14 and the insulating layer 15 including a lot of contact holes formed therein is made of an organic material.

FIG. 4 shows contact holes CH1, CH2, and CH3 among the lot of contact holes included in the substrate structure SUB1. The contact hole CH1 is an opening for connecting the terminal pattern TP1 and the conductor pattern MP1 of the wiring layer WL3. The contact hole CH2 is an opening for connecting the terminal pattern TP2 and the conductor pattern MP2 of the wiring layer WL3. The contact hole CH3 is an opening for connecting the conductor pattern MP1 of the wiring layer WL3 and the wiring pattern MW1 of the wiring layer WL2.

The wiring layer WL3 includes a conductor pattern MP1 electrically connected to the terminal pattern TP1 through the contact hole CH1 formed in the insulating layer 15 and a conductor pattern MP2 made of the same metal as that of the conductor pattern MP1 and electrically connected to the terminal pattern TP2 through the contact hole CH2 formed in the insulating layer 15.

The conductor pattern MP1 has a flat portion connected to the terminal pattern TP1 at a bottom surface of the contact hole CH1 and a contact portion embedded in the contact hole CH3 and connected to the wiring layer WL2. As shown in FIG. 3, the conductor pattern MP2 is a large-area pattern that spreads over the plurality of pixels PIX.

Each of the wiring pattern MW1, the conductor pattern MP1, the conductor pattern MP2, the terminal pattern TP1, and the terminal pattern TP2 shown in FIG. 4 is made of, for example, the same metal material as one another. As an example, a TAT structure that is a stacking film of a titanium layer made of titanium, an aluminum layer made of aluminum, and a titanium layer made of titanium, can be exemplified. However, there are various modification examples of the metal material configuring the wiring pattern MW1, the conductor pattern MP1, the conductor pattern MP2, the terminal pattern TP1, and the terminal pattern TP2. For example, a stacking film made of the titanium layer and the aluminum layer may be applied.

In the present embodiment, the wiring layer WL3 includes a metal layer 41 configuring the diode element 40, a metal oxide layer 42 covering the metal layer 41, and a metal layer 43 covering the metal layer 41 through the metal oxide layer 42. The diode element 40 is a stacking film including the metal layer 41 being the cathode electrode 40EC, the metal oxide layer 42 covering the metal layer 41, and the metal layer 43 being the anode electrode 40EA and covering the metal layer 41 through the metal oxide layer 42. The diode element 40 is a diode having a Metal-Insulator-Metal (MIM) structure in which the metal oxide layer 42 is sandwiched between the metal layer 41 and the metal layer 43. In the diode having the MIM structure, a metal material configuring the metal layer 41 and a metal material configuring the metal layer 43 differ from each other. In the case of the present embodiment, for example, the metal layer 41 is made of tantalum (Ta), and the metal layer 43 is made of chromium (Cr). The metal oxide layer 42 is a metal oxide film (made of, for example, tantalum oxide), and can be formed by oxidation of a positive electrode of a surface of the metal layer 41.

The diode element 40 that is the diode having the MIM structure uses difference between a work function of the metal configuring the metal layer 41 and a work function of the metal configuring the metal layer 43. When bias is applied between the metal layer 41 and the metal layer 43, electrons are moved by a tunnel effect. Since there is the difference between the work function of the metal configuring the metal layer 41 and the work function of the metal configuring the metal layer 43, a shape of a tunnel burrier is unsymmetric, the tunnel barrier is different between the forward bias and the reverse bias. In other words, the diode element 40 behaves as a tunnel diode.

In the case of the diode having the MIM structure, a metal layer made of a metal having a higher work function serves as the anode. For example, in the example of the present embodiment, the work function of chromium configuring the metal layer 43 is higher than the work function of tantalum configuring the metal layer 41, and therefore, the metal layer 43 corresponds to the anode electrode 40EA, and the metal layer 41 corresponds to the cathode electrode 40EC.

A manufacturing process of the diode element 40 having the MIM structure is made simpler than that of a diode element including a semiconductor layer described later as a modification example.

As shown in FIG. 4, the metal layer 43 that is the anode electrode 40EA of the diode element 40 is connected to the terminal pattern TP2 through the conductor pattern MP2. In other words, the anode electrode 40EA of the diode element 40 and the cathode electrode 20EC of the LED element 20 are electrically connected to each other through the conductor pattern MP2 and the terminal pattern TP2.

The metal layer 41 that is the cathode electrode 40EC of the diode element 40 is connected to the terminal pattern TP1 through the conductor pattern MP1. In other words, the cathode electrode 40EC of the diode element 40 and the anode electrode 20EA of the LED element 20 are electrically connected to each other through the conductor pattern MP1 and the terminal pattern TP1.

Note that FIG. 4 is the enlarged cross-section view taken along the line A-A in FIG. 3, and therefore, does not show ta contact portion between the conductor pattern MP1 and the metal layer 41. However, as shown in FIG. 3, a portion of the conductor pattern MP1 overlaps a portion of the metal layer 41. FIG. 4 schematically shows a dashed double-dotted line connecting the conductor pattern MP1 and the metal layer 41 to clearly show that the conductor pattern MP1 and the metal layer 41 are electrically connected to each other.

As described in detail later, the diode element 40 exerts a function when the electroplating method is used for the step of forming the bump electrode 30 and the bump electrode 31 shown in FIG. 4. When the display apparatus DSP1 is used, the diode element 40 does not function as the drive circuit unless a voltage is applied in the forward direction of the diode element 40. Therefore, even if the diode element 40 is present when the display apparatus DSP1 is used, the drive circuit does not malfunction due to the presence of the diode element 40.

The wiring layer WL4 is a wiring layer arranged in the topmost wiring layer among the plurality of wiring layers. The wiring layer WL4 is covered with an insulating layer 16 that is an inorganic insulating layer made of an inorganic material. However, an opening is partially formed in the insulating layer 16, and the wiring layer WL4 is electrically connected to the bump electrode 30 or the bump electrode 31 at the opening formed in the insulating layer 16. The wiring layer WL4 includes the terminal pattern (terminal, conductor pattern) TP1 electrically connected to the anode electrode 20EA of the LED element 20A and the terminal pattern (terminal, conductor pattern) TP2 electrically connected to the cathode electrode 20EC of the LED element 20A.

The terminal pattern TP1 has a terminal portion (also called a flat portion) connected to the bump electrode 30 at the opening of the insulating layer 16, and a contact portion embedded in the contact hole CH1 and connected to the wiring layer WL3. The contact portion is covered with the insulating layer 16. Similarly, the terminal pattern TP2 has a terminal portion connected to the bump electrode 31 at the opening of the insulating layer 16 and a contact portion embedded in the contact hole CH2 and connected to the wiring layer WL3. The contact portion is covered with the insulating layer 16. Each of the terminal patterns TP1 and TP2 is an external terminal of the substrate structure SUB1.

### <Regarding Bump Electrode>

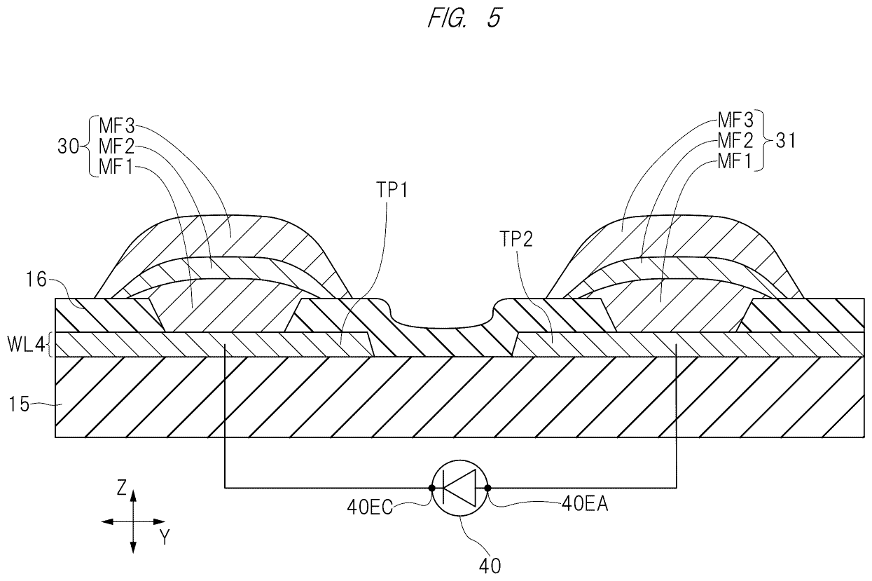

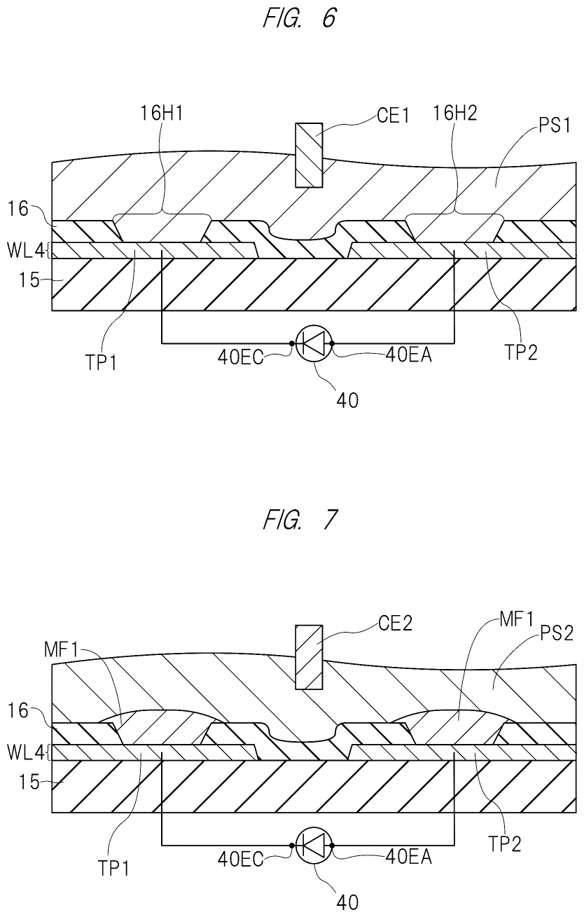

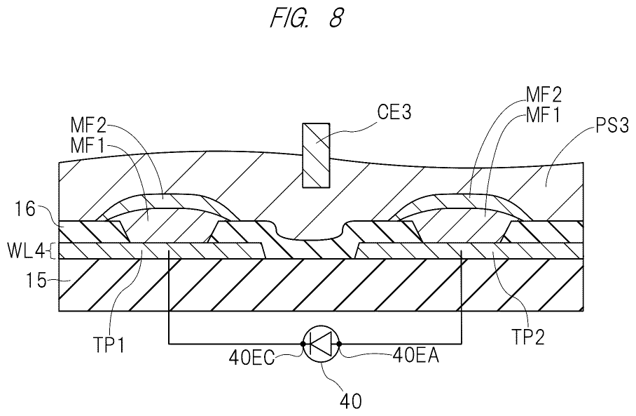

FIG. 5 is an enlarged cross-sectional view showing a detailed structure example of the bump electrode shown in FIG. 4. FIG. 6 is an enlarged cross-sectional view showing a step of forming the first-layer metal film on the terminal pattern shown in FIG. 5. FIG. 7 is an enlarged cross-sectional view showing a step of forming the second-layer metal film on the terminal pattern shown in FIG. 5. FIG. 8 is an enlarged cross-sectional view showing a step of forming the third-layer metal film on the terminal pattern shown in FIG. 5.

Note that FIG. 5 shows a state provided before the LED element 20 is mounted on the bump electrodes 30 and 31 shown in FIG. 4. As shown in FIG. 5, each of the bump electrode 30 and the bump electrode 31 is made of, for example, a stacking film of a plurality of metal films. In the example shown in FIG. 5, the stacking film is a stacking film having a three-layer structure made of a metal film MF1, a metal film MF2, and a metal film MF3 stacked in this order from the terminal pattern TP1 side. The metal film MF1 is, for example, a copper film, the metal film MF2 is, for example, a nickel film, and the metal film MF3 is, for example, a tin film.

In a step of manufacturing the display apparatus DSP1 (see FIG. 4), each of the metal film MF1, the metal film MF2, and the metal film MF3 is formed by the electroplating method. In a bump-electrode forming step using the electroplating method, for example, a plurality of metal films are formed as described below.

First, in a first-metal-film forming step shown in FIG. 13 described later, as shown in FIG. 6, each of the terminal patterns TP1 and TP2 is brought into contact with plating solution PS1 containing a metal ion (such as copper ion) configuring the metal film MF1 (see FIG. 5) in a state in which an electric potential is supplied to each of the terminal patterns TP1 and TP2. More specifically, portions of the terminal pattern TP1 and the terminal pattern TP2, the portion being exposed from the insulation layer 16 at the openings 16H1 and 16H2 formed in the insulation layer 16, are brought into contact with the plating solution PS1.

A negative-electrode member CE1 is immersed in the plating solution PS1, and an electric current flows between the terminal patterns TP1 and TP2 functioning as a positive electrode and the negative-electrode member CE1. As a result, the metal (copper) is deposited on the respective surfaces of the terminal pattern TP1 and the terminal pattern TP2 to form the metal film MF1 (see FIG. 7).

Next, in a step of forming the metal film MF2 (that is a second-metal-film forming step shown in FIG. 13 described later), as shown in FIG. 7, each of the metal film MF1 on the terminal patterns TP1 and the metal film MF1 on the terminal TP2 is brought into contact with plating solution PS2 containing a metal ion (such as nickel ion) configuring the metal film MF2 (see FIG. 5) in a state in which an electric potential is supplied to each of the terminal patterns TP1 and TP2.

A negative-electrode member CE2 is immersed in the plating solution PS2, and an electric current flows between the metal film MF1 on the terminal patterns TP1 and the metal film MF1 on the terminal TP2 functioning as a positive electrode and the negative-electrode member CE2. As a result, the metal (nickel) is deposited on the respective surfaces of the metal film MF1 on the terminal patterns TP1 and the metal film MF1 on the terminal TP2 to form the metal film MF2 (see FIG. 8).

Next, in a step of forming the metal film MF3 (that is a third-metal-film forming step shown in FIG. 13 described later), as shown in FIG. 8, each of the metal film MF2 on the terminal patterns TP1 and the metal film MF2 on the terminal TP2 is brought into contact with plating solution PS3 containing a metal ion (such as tin ion) configuring the metal film MF3 (see FIG. 5) in a state in which an electric potential is supplied to each of the terminal patterns TP1 and TP2.

A negative-electrode member CE3 is immersed in the plating solution PS3, and an electric current flows between the metal film MF2 on the terminal patterns TP1 and the metal film MF2 on the terminal TP2 functioning as a positive electrode and the negative-electrode member CE3. As a result, the metal (tin) is deposited on the respective surfaces of the metal film MF2 on the terminal patterns TP1 and the metal film MF2 on the terminal TP2 to form the metal film MF3 (see FIG. 5).

Thus, when the bump electrode 30 and the bump electrode 31 are formed by the electroplating method, it is necessary to supply the electric potential to each of the terminal pattern TP1 and the terminal pattern TP2. Here, as shown in FIG. 5, when the terminal patterns TP1 and TP2 are electrically connected to each other through the diode element 40, if the potential is supplied to the terminal pattern TP2 connected to the anode electrode 40EA, the same potential is supplied to the terminal pattern TP1 connected to the cathode electrode 40EC. Strictly speaking, note that the potential that is supplied to the terminal pattern TP1 is smaller than the potential that is supplied to the terminal pattern TP2 due to an impedance component of the diode element 40. However, its difference is small enough to be regarded so that the potentials are substantially the same potential as each other in the electroplating.

Thus, according to the present embodiment, the terminal pattern TP1 and the terminal pattern TP2 are electrically connected to each other through the diode element 40, and therefore, the potential can be easily supplied to each of the terminal pattern TP1 and the terminal pattern TP2 in the step of forming the bump electrode 30 and the bump electrode 31 by the electroplating method.

As described above, the diode element 40 interposes in the path electrically connecting the terminal pattern TP1 and the terminal pattern TP2. As explained with reference to FIG. 2, the anode electrode 40EA of the diode element 40 is connected to the cathode electrode 20EC of the LED element 20, and the cathode electrode 40EC of the LED element 40 is connected to the anode electrode 20EA of the LED element 20. Therefore, even if the diode element 40 is not removed after the bump electrode 30 and the bump electrode 31 are formed, the driving of the display apparatus DSP1 is not affected.

In FIGS. 5 to 8, the embodiment in which each of the bump electrode 30 and the bump electrode 31 is made of the metal film having the three-layer structure has been described. When each of the bump electrode 30 and the bump electrode 31 includes the metal film MF1 made of copper having the higher electrical conductivity than those of nickel and tin, the electrical property of the bump electrode 30 and the bump electrode 31 can be improved.

In addition, since the metal film MF1 of each of the bump electrode 30 and the bump electrode 31 is covered with the metal film MF2 made of nickel, the oxidation of the surface of the metal film MF1 can be suppressed.

When each of the bump electrode 30 and the bump electrode 31 includes the metal film MF3 made of tin, each of the bump electrode 30 and the bump electrode 31 has a property functioning as a solder bump. Therefore, the connections between the bump electrode 30 and the anode electrode 20EA of the LED element 20 and between the bump electrode 31 and the cathode electrode 20EC of the LED element 20 shown in FIG. 4 can be easily made.

Note that various modification examples can be applied to the structures of the bump electrode 30 and the bump electrode 31. For example, each of the bump electrode 30 and the bump electrode 31 may have a one-layer structure made of only the metal film MF3 made of tin.

Alternatively, each of the bump electrode 30 and the bump electrode 31 may be made of a two-layer structure made of the metal film MF1 made of copper and the metal film MF3 formed to cover the metal film MF1.

As shown in FIG. 4, the substrate structure SUB1 includes the plurality of wiring layers including the wiring layer WL4 and the plurality of insulating layers including the insulating layer 15. The terminal pattern TP1 and the terminal pattern TP2 are formed in the wiring layer WL4 on the insulating layer 15. The diode element 40 is formed in a wiring layer (in the example shown in FIG. 4, the wiring layer WL3) different from the wiring layer WL4.

When the diode element 40 is formed in a wiring layer different from the wiring layer WL4 arranged at the topmost layer of the substrate structure SUB1, the flatness of the surface of the substrate structure SUB1 caused by the formation of the diode element 40 can be improved.

As shown in FIG. 4, in the thickness direction (Z direction) of the substrate structure SUB1, the diode element 40 is arranged at a position overlapping the LED element 20. In other words, as shown in FIG. 3, the diode element 40 overlaps the LED element 20 in transparent plan view.

When the diode element 40 is arranged at a position overlapping the LED element 20, space loss caused by the formation of the diode element 40 in plan view can be reduced.

### Modification Example

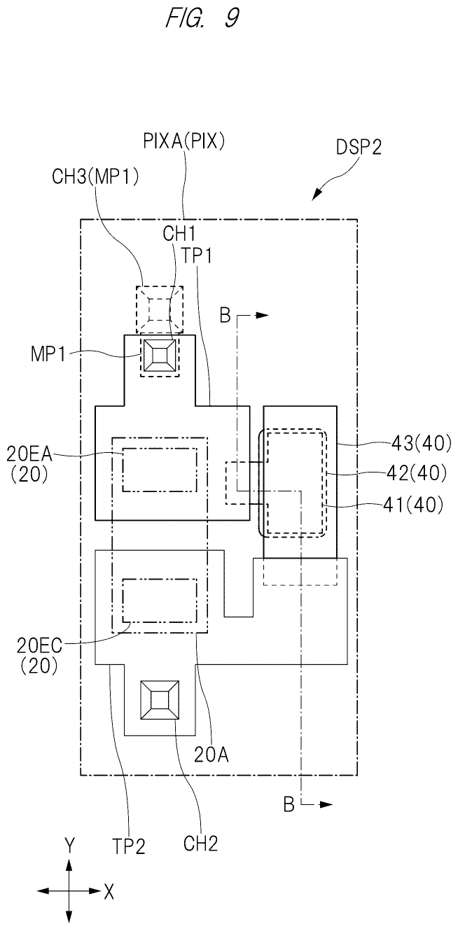

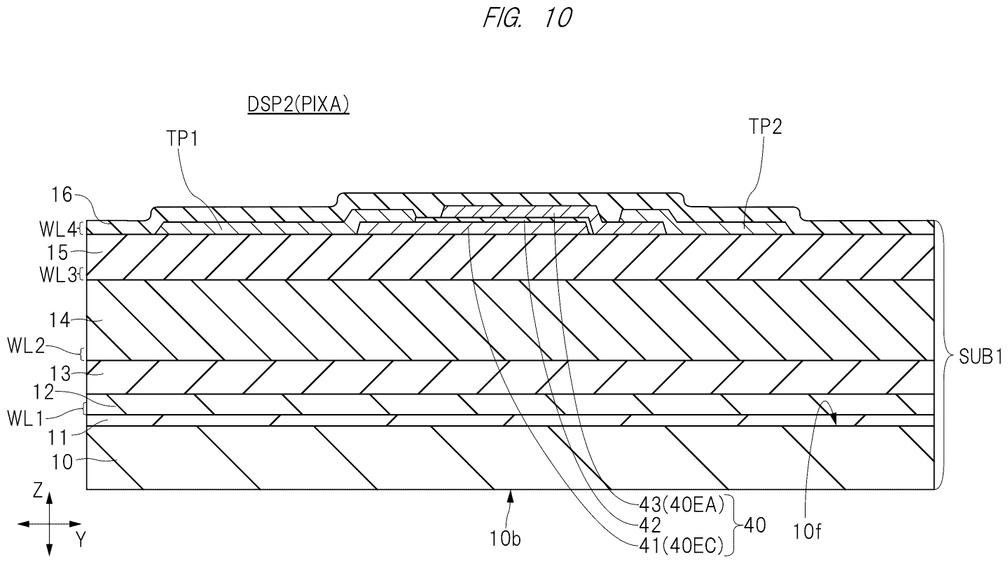

Next, a modification example will be described. FIG. 9 is a transparent plan view showing one pixel of the display apparatus as a modification example relative to FIG. 3. FIG. 10 is an enlarged cross-sectional view taken along a line B-B of FIG. 9. In FIG. 9, as similar to FIG. 3, the conductor pattern arranged in the wiring layer WL4 shown in FIG. 10 is illustrated with a solid line, the conductor pattern MP1 arranged in the wiring layer WL3 is illustrated with a dotted line, and outlines of the LED element 20 and the electrode included in the LED element 20 are illustrated with a dashed double-dotted line. However, each of a portion of the metal layer 41 arranged in the wiring layer WL4, the portion being covered with the metal oxide layer 42 or the terminal pattern TP1, a portion of the metal oxide layer 42, the portion being covered with the metal layer 43, and a portion of the metal layer 43, the portion being covered with the terminal pattern TP2, is illustrated with a dotted line. FIG. 9 representatively shows only the portion corresponding to the pixel PIXA among the pixels PIXA, PIXB, and PIXC shown in FIG. 3.

The display apparatus DSP2 shown in FIGS. 9 and 10 differs from the display apparatus DSP1 shown in FIGS. 3 and 4 in that the diode element 40 is formed in the wiring layer WL4 that is the same layer as those of the terminal patterns TP1 and TP2.

The structure of the display apparatus DSP2 can be expressed as follows. The terminal pattern TP1 and the terminal pattern TP2 are arranged on the insulating layer 15. The diode element 40 is formed on the insulating layer 15.

When the diode element 40 is arranged in the same layer as those of the terminal patterns TP1 and TP2 as described in the present modification example, the diode element 40 is not formed in the wiring layer WL3 as different from the display apparatus DSP1 shown in FIG. 4. Therefore, the thickness of the insulating layer 15 can be made smaller than that of the display apparatus DSP1.

On the other hand, in the case of the display apparatus DSP2, the LED element 20 and the diode element 40 are not allowed to overlap each other in the thickness direction as described in the display apparatus DSP1. Therefore, a size of one pixel PIX can be made smaller in the display apparatus DSP1.

The display apparatus DSP2 shown in FIGS. 9 and 10 is the same as the display apparatus DSP1 shown in FIGS. 3 and 4 except for the above-described differences. Therefore, the overlapping explanation for the display apparatus DSP2 with the explanation for the display apparatus DSP1 will be omitted.

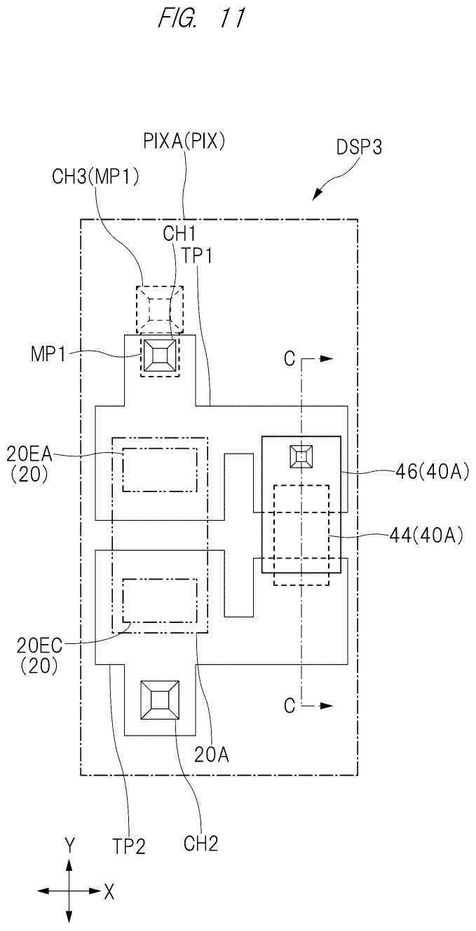

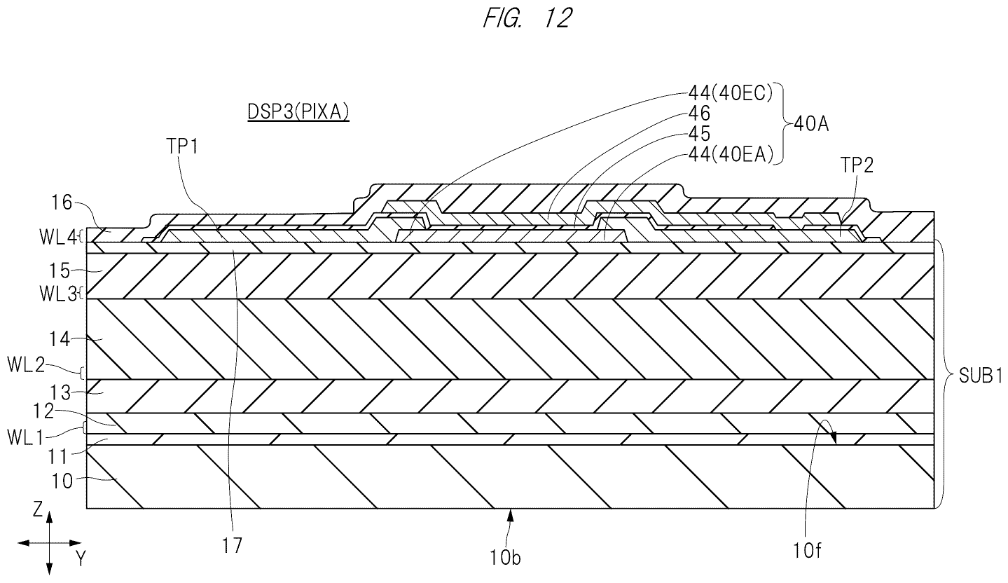

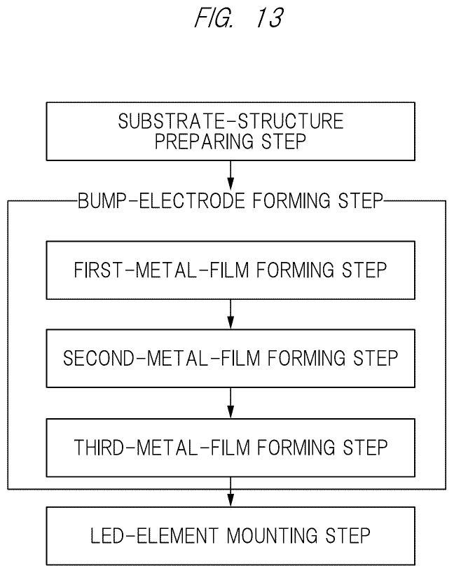

FIG. 11 is a transparent plan view showing a modification example relative to a diode element shown in FIG. 9. FIG. 12 is an enlarged cross-sectional view taken along a line C-C in FIG. 11. In FIG. 11, as similar to FIG. 9, the conductor pattern arranged in the wiring layer WL4 shown in FIG. 12 is illustrated with a solid line, the conductor pattern MP1 arranged in the wiring layer WL3 is illustrated with a dotted line, and each of outlines of the LED element 20 and the electrode included in the LED element 20 is illustrated with a dashed double-dotted line. However, each of the entire semiconductor layer 44 arranged in the wiring layer WL4 and a portion of the terminal pattern TP1 and the terminal pattern TP2, the portion being covered with the metal layer 46, is illustrated with a dotted line. FIG. 11 representatively shows only the portion corresponding to the pixel PIXA among the pixels PIXA, PIXB, and PIXC shown in FIG. 3.

The display apparatus DSP3 shown in FIGS. 11 and 12 differs from the structure of the diode element 40 of the display apparatus DSP2 shown in FIGS. 9 and 10 in a structure of a diode element 40A. The diode element 40A differs from the diode element 40 having the MIM structure because of having the semiconductor layer 44.

As similar to the diode element 40, the diode element 40A is an element for easily achieving the electroplating in the step of forming the bump electrodes 30 and 31 (see FIG. 4). Therefore, the diode element 40A includes a cathode electrode 40EC connected to the terminal pattern TP1 and an anode electrode 40EA connected to the terminal pattern TP2. The diode element 40 is not limited to have the MIM structure when satisfying this condition, and the diode element 40A using the semiconductor layer 44 as described in the present modification example can be used.

When the semiconductor layer 44 is formed, an inorganic insulating film made of silicon oxide, silicon nitride or others is preferable as a base member of the semiconductor layer 44. In the present modification example, an insulating layer 17 that is an inorganic insulating layer is arranged on the insulating layer 15 that is the organic insulating layer, and each of the semiconductor layer 44, the terminal pattern TP1 and the terminal pattern TP2 is formed on the insulating layer 17.

A region of the semiconductor layer 44, the region being connected to the terminal pattern TP1, functions as the cathode electrode 40EC. A region of the semiconductor layer 44, the region being connected to the terminal pattern TP2, functions as the anode electrode 40EA. Note that FIG. 12 shows an example in which each of the terminal pattern TP1 and the terminal pattern TP2 is directly connected to the semiconductor layer 44. As another modification example relative to the present modification example, a metal film functioning as an electrode may interpose between each of the terminal pattern TP1 and the terminal pattern TP2 and the semiconductor layer 44.

The semiconductor layer 44 is covered with the insulating film 45. On the insulating film 45, the metal layer 46 is formed. The diode element 40A has the similar structure to that of the Thin Film Transistor (TFT). The metal layer 46 corresponds to the gate electrode of the TFT, and the insulating film 45 corresponds to the gate insulating film of the TFT. A portion of the semiconductor layer 44, the portion being exposed from the terminal pattern TP1 and the terminal pattern TP2 and facing the metal layer 46 through the insulating film 45, functions as a channel when a forward bias is applied thereto.

In the case of the diode element 40A, the metal layer 46 corresponds to the gate electrode is electrically connected to the terminal pattern TP2. The diode element 40A differs from the TFT in this point.

When the forward bias is applied to the diode element 40A, in other words, when the potential is supplied to the terminal pattern TP2 of the diode element 40A, the potential is also supplied to the metal layer 46 through the terminal pattern TP2. In this manner, a channel is formed in the semiconductor layer 44, and carriers (electrons or holes) move from the anode electrode 40EA to the cathode electrode 40EC.

When a reverse bias is applied to the diode element 40A, in other words, when the potential is supplied to the terminal pattern TP1 of the diode element 40A, the potential is not supplied to the metal layer 46, and therefore, the channel is not formed in the semiconductor layer 44. Therefore, it is difficult to supply the potential to the terminal pattern TP2. As described above, the diode element 40A functions as the diode having the rectifying function.

A response speed of the diode element 40A including the semiconductor layer 44 is faster than that of the diode element 40 having the MIM structure shown in FIG. 10.

Meanwhile, the diode element 40 having the MIM structure is easier to be manufactured than the diode element 40A. For example, it is unnecessary to arrange the insulating layer 17 (see FIG. 12) that is the inorganic insulating layer as the base layer, and therefore, the diode element 40 can be formed on the insulating layer 15 or the insulating layer 14 that is the organic insulating layer.

The diode element 40A is formed as, for example, described below. Note that the semiconductor layer 44 is formed on the insulating layer 17 that is the base layer first as described below. The semiconductor layer 44 can be deposited by, for example, a Chemical Vapor Deposition (CVD) method. Next, the terminal pattern TP1 and the terminal pattern TP2 are deposited by, for example, the CVD method, and then, are patterned by etching. Next, the insulating film 45 is formed to cover the terminal pattern TP1, the terminal pattern TP2 and the semiconductor layer 44. For example, if silicon oxide is used for the insulating film 45, a method of forming a silicon film by the CVD method, and then, oxidizing the film by a thermal oxidization method can be used. Next, an opening is formed in a part of the insulating film 45 to expose a part of the terminal pattern TP2 from the insulating film 45. This opening becomes a contact hole for electrically connecting the metal layer 46 and the terminal pattern TP2. Next, the metal layer 46 is deposited on the insulating film 45 by, for example, the CVD method.

Although not illustrated, the diode element 40A may be formed in the wiring layer WL3 (in other words, on the insulating layer 14) as similar to the diode element 40 shown in FIG. 4. In this case, the LED element 20 and the diode element 40A can be formed to overlap each other in the thickness direction of the substrate structure SUB1. However, when the diode element 40A is formed on the insulating layer 14, it is preferred that the insulating layer 17 that is the inorganic insulating layer shown in FIG. 12 is formed on the insulating film 14 while the diode element 40A is formed on the insulating layer 17.

Although there is limitation in terms of space, the diode element 40A may be formed in the same layer as that of the drive transistor DRT shown in FIG. 4. In this case, the semiconductor layer 44 is formed on the insulating layer 12 that is the inorganic insulating layer, and therefore, the insulating layer 17 shown in FIG. 12 is unnecessary. In the example shown in FIG. 4, the drive transistor DRT has the bottom gate system in which the gate electrode EG is arranged in the lower layer of the semiconductor layer 50. Therefore, when the diode element 40A is formed in the same layer as that of the drive transistor DRT, the metal layer 46 shown in FIG. 12 is formed in the wiring layer WL1 as similar to the gate electrode EG shown in FIG. 4. Alternatively, the top gate structure in which each of the gate electrode EG and the metal layer 46 is formed in the layer upper than the semiconductor layers 50 and 44 may be applied.

The display apparatus DSP3 shown in FIGS. 11 and 12 is the same as the display apparatus DSP2 shown in FIGS. 9 and 10 except for the above-described differences. Therefore, the overlapping explanation for the display apparatus DSP3 with the explanation for the display apparatus DSP1 or the display apparatus DSP2 will be omitted.

### <Method of Manufacturing Display Apparatus>

Next, a method of manufacturing the display apparatus including the above-described bump-electrode forming step will be described. FIG. 13 is a flowchart showing an example of the method of manufacturing the display apparatus. The method of manufacturing the display apparatus shown in FIG. 13 includes a substrate-structure preparing step, a bump-electrode forming step and an LED-element mounting step.

In the substrate-structure preparing step shown in FIG. 13, the substrate structure SUB1 shown in FIG. 4, 10 or 12 is prepared. The substrate-structure preparing step includes a step of stacking the plurality of wiring layers (wiring layers WL1, WL2, WL3 and WL4) and the plurality of insulating layers (insulating layers 11, 12, 13, 14 and 15) on the surface 10f of the substrate 10.

The substrate-structure preparing step includes a diode-element forming step of forming the diode element 40 shown in FIG. 4 or 10 or the diode element 40A shown in FIG. 12. The diode-element forming step is performed, for example, after forming the insulating layer 14, after forming the insulating layer 15 or at the same time as a step of forming the drive transistor DRT (see FIG. 4). The method of forming the diode element 40 and the method of forming the diode element 40A have been described above, and therefore, the overlapping explanation thereof will be omitted.

The substrate-structure preparing step includes a termina-pattern forming step of forming the terminal pattern TP1 and the terminal pattern TP2 shown in FIG. 3, 9 or 11.

Next, the bump-electrode forming step shown in FIG. 13 includes a first-metal-film forming step, a second-metal-film forming step, and a third-metal-film forming step. However, as described above, as a modification example relative to FIG. 13, either one or both of the first-metal-film forming step and the second-metal-film forming step may be excluded.

In the metal-film forming step shown in FIG. 13 and as described with reference to FIGS. 5 to 8, the plating process is performed while the electric current flows in both the terminal pattern TP1 and the terminal pattern TP2 by the electroplating method, and, as a result, the metal film is deposited on the terminal pattern TP1 and the terminal pattern TP2. The metal film that is deposited on the terminal pattern TP1 in the metal film that is deposited by this step becomes the bump electrode 30 shown in FIG. 5, while the metal film that is deposited on the terminal pattern TP2 therein becomes the bump electrode 31 shown in FIG. 5.

As shown in FIG. 5, the bump electrode 30 is selectively formed in a part of the terminal pattern TP1, and the bump electrode 31 is selectively formed in a part of the terminal pattern TP2. A part of each of the terminal pattern TP1 and the terminal pattern TP2 is exposed from the insulating layer 16 at the opening 16H1 (see FIG. 6) or an opening 16H2 formed in a part of the insulating layer 16. In this step, the bump electrodes 30 and 31 are selectively formed while the insulating layer 16 is used as a mask.

In the first-metal-film forming step shown in FIG. 13, the metal film MF1 (see FIG. 7) is selectively formed on the terminal pattern TP1 and on the terminal pattern TP2 by the electroplating method. The details of the first-metal-film forming step have been described above with reference to FIG. 6, and therefore, the overlapping explanation thereof will be omitted.

In the second-metal-film forming step, the metal film MF2 (see FIG. 8) is formed on the metal film MF1 (see FIG. 7) by the electroplating method. The details of the second-metal-film forming step have been described above with reference to FIG. 7, and therefore, the overlapping explanation thereof will be omitted.

In the third-metal-film forming step, the metal film MF3 (see FIG. 5) is formed on the metal film MF2 (see FIG. 8) by the electroplating method. The details of the third-metal-film forming step have been described above with reference to FIG. 8, and therefore, the overlapping explanation thereof will be omitted.

Next, in the LED-element mounting step shown in FIG. 13, the LED element 20 shown in FIG. 14 is prepared, the anode electrode 20EA and the bump electrode 30 are connected to each other, and the cathode electrode 20EC and the bump electrode 31 are connected to each other. In this step, for example, by laser irradiation not illustrated, a contact interface between the anode electrode 20EA and the bump electrode 30 and a contact interface between the cathode electrode 20EC and the bump electrode 31 are heated. In this manner, the anode electrode 20EA and the bump electrode 30 are electrically connected to each other, and the cathode electrode 20EC and the bump electrode 31 are electrically connected to each other.

In the display apparatus DSP1 described with reference to FIGS. 3 and 4, in the LED-element mounting step, the LED element 20 is mounted at a position overlapping the diode element 40 in the thickness direction of the substrate structure SUB1.

The embodiments and the typical modification examples have been described above. The above-described technique is also applicable to various modification examples other than the exemplified modification examples. For example, the above-described modification examples may be combined with each other.

In the scope of the idea of the present invention, various modification examples and alteration examples can be easily conceived by those who are skilled in the art, and it would be understood that these various modification examples and examples also belong to the scope of the present alteration invention. For example, the ones obtained by appropriate addition, removal, or design-change of the components to/from/into each of the above-described embodiments or obtained by addition, omitting, or condition-change of the step to/from/into each of the above-described embodiments by those who are skilled in the art are also within the scope of the present invention as long as the ones include the concept of the present invention.

The present invention is applicable to a display apparatus and an electronic device into which the display apparatus is embedded.

What is claimed is:

1. A display apparatus comprising:
a first diode element including a first anode electrode and a first cathode electrode, and being an inorganic light emitting diode element; and
a substrate structure on which the first diode element is mounted,
wherein the substrate structure includes:
a first terminal connected to the first anode electrode;
a second terminal connected to the first cathode electrode;
a second diode element electrically connected to each of the first terminal and the second terminal;
a first bump electrode formed on the first terminal and electrically connected to each of the first terminal and the first anode electrode; and
a second bump electrode formed on the second terminal and electrically connected to each of the second terminal and the first cathode electrode,
the second diode element includes:
a second cathode electrode connected to the first terminal; and
a second anode electrode connected to the second terminal.

2. The display apparatus according to claim 1,
wherein each of the first bump electrode and the second bump electrode is made of a stacking film of a plurality of metal films.

3. The display apparatus according to claim 1,
wherein the substrate structure includes a plurality of wiring layers including a first wiring layer and a plurality of insulating layers including a first insulating layer,
the first terminal and the second terminal are formed in the first wiring layer arranged on the first insulating layer, and
the second diode element is formed in a wiring layer different from the first wiring layer.

4. The display apparatus according to claim 3,
wherein the second diode element is arranged at a position overlapping the first diode element in a thickness direction of the substrate structure.

5. The display apparatus according to claim 1,
wherein the first terminal and the second terminal are arranged on a first insulating layer, and
the second diode element is formed on the first insulating layer.

6. The display apparatus according to claim 1,
wherein the second diode element is made of a stacking film,
the stacking film including:
a first metal layer being the second cathode electrode;
a metal oxide layer covering the first metal layer; and
a second metal layer being the second anode electrode and covering the first metal layer through the metal oxide layer.

7. The display apparatus according to claim 1,
wherein the second diode element includes a semiconductor layer.

8. A method of manufacturing a display apparatus comprising steps of:
(a) preparing a substrate structure including a first terminal and a second terminal;
(b) forming a first bump electrode on the first terminal and a second bump electrode on the second terminal;
(c) preparing a first diode element including a first anode electrode and a first cathode electrode and being an inorganic light emitting diode element, and connecting the first anode electrode to the first bump electrode while connecting the first cathode electrode to the second bump electrode,
wherein the substrate structure includes a second diode element electrically connected to each of the first terminal and the second terminal,
the second diode element includes:
a second cathode electrode connected to the first terminal; and
a second anode electrode connected to the second terminal, and
the step (b) includes a step of forming the first bump electrode and the second bump electrode by an electroplating method.

9. The method of manufacturing the display apparatus according to claim 8,
wherein the step (b) further includes steps of:
(b1) selectively forming a first metal film on the first terminal and the second terminal by an electroplating method; and
(b2) forming a second metal film on the first metal film by an electroplating method.

10. The method of manufacturing the display apparatus according to claim 8,
wherein, in the step (c), the second diode element is mounted at a position overlapping the second diode element in a thickness direction of the substrate structure.

11. The method of manufacturing the display apparatus according to claim 8,
wherein the second diode element is made of a stacking film,
the stacking film including:
a first metal layer being the second cathode electrode;
a metal oxide layer covering the first metal layer; and
a second metal layer being the second anode electrode and covering the first metal layer through the metal oxide layer.
